(19) United States
(12) Patent Application Publication
(10) Pub. No.: US 2025/0391660 A1
(43) Pub. Date: Dec. 25, 2025

(54) NON-UNIFORM PATTERNING IN ION IMPLANTATION

(71) Applicant: Applied Materials, Inc., Santa Clara, CA (US)

(72) Inventors: Supakit CHARNVANICHBORIKARN, Gloucester, MA (US); William Robert BOGIAGES, JR., Danvers, MA (US); Wei ZOU, Lexington, MA (US); Pratim PALIT, Reading, MA (US)

(73) Assignee: Applied Materials, Inc., Santa Clara, CA (US)

(21) Appl. No.: 18/752,416

(22) Filed: Jun. 24, 2024

(51) Int. Cl. H01L 21/265; H01L 21/04; H01L 21/66

(52) U.S. Cl. CPC H01L 21/26553; H01L 21/046; H01L 22/14; H01L 2021/26573

(57) ABSTRACT

A method for improving doping uniformity in a semiconductor substrate, including placing the semiconductor substrate in an epitaxial growth chamber, performing an epitaxial doping process on the semiconductor substrate, whereafter a first portion of the semiconductor substrate exhibits a first average doping concentration level and a second portion of the semiconductor substrate exhibits a second average doping concentration level, where there is first difference between the first average doping concentration level and the second average doping concentration level, transferring the substrate to a process chamber of an ion implantation system, and performing a non-uniform ion implantation process on the semiconductor substrate to create a second difference between the first average doping concentration level and the second average doping concentration level, where the second difference is less than the first difference.

### FIELD OF THE DISCLOSURE

Embodiments of the present disclosure relate to the manufacture of semiconductor devices, and more particularly, to methods for improving doping uniformity in semiconductor substrates.

### BACKGROUND OF THE DISCLOSURE

Epitaxial doping is a process used in semiconductor manufacturing to introduce specific impurities into a crystalline semiconductor substrate with precise control. The process involves growing a thin layer (an “epitaxial layer”) of semiconductor material on top of a crystalline substrate, where dopant atoms are strategically incorporated during the growth process. This method allows for the creation of semiconductor structures with tailored electrical properties, such as higher conductivity or altered electronic behavior, essential for the fabrication of advanced electronic devices like transistors and diodes. Epitaxial doping plays a crucial role in semiconductor fabrication, enabling the production of complex integrated circuits with enhanced performance and functionality.

The problem of non-uniform doping across a semiconductor wafer in epitaxial doping arises due to variations in the distribution of dopant atoms during the epitaxial growth process. Despite efforts to control deposition conditions, factors such as temperature gradients, gas flow variations, and reactor geometry can lead to inconsistencies in dopant incorporation. As a result, the doping concentration may vary spatially across a wafer surface, leading to non-uniform electrical properties in the epitaxial layer. Non-uniform doping can have detrimental effects on semiconductor device performance and yield. Variations in doping concentration can affect device characteristics such as threshold voltage, carrier mobility, and junction depths, leading to unpredictable behavior and decreased device reliability. Moreover, non-uniform doping can result in mismatches between adjacent devices on the wafer, compromising the functionality and performance of integrated circuits, and creating yield loss.

With respect to these and other considerations the present disclosure is provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

A method for improving doping uniformity in a semiconductor substrate in accordance with an embodiment of the present disclosure may include placing the semiconductor substrate in an epitaxial growth chamber, performing an epitaxial doping process on the semiconductor substrate, whereafter a first portion of the semiconductor substrate exhibits a first average doping concentration level and a second portion of the semiconductor substrate exhibits a second average doping concentration level, where there is first difference between the first average doping concentration level and the second average doping concentration level, transferring the substrate to a process chamber of an ion implantation system, and performing a non-uniform ion implantation process on the semiconductor substrate to create a second difference between the first average doping concentration level and the second average doping concentration level, where the second difference is less than the first difference.

Another method for improving doping uniformity in a semiconductor substrate in accordance with an embodiment of the present disclosure may include placing the semiconductor substrate in an epitaxial growth chamber, performing an epitaxial doping process on the semiconductor substrate, whereafter a first portion of the semiconductor substrate exhibits a first average doping concentration level and a second portion of the semiconductor substrate exhibits a second average doping concentration level, where there is first difference between the first average doping concentration level and the second average doping concentration level, transferring the substrate to a process chamber of an ion implantation system, performing an analysis of the semiconductor substrate to determine a doping profile of the semiconductor substrate, storing the doping profile as a set of data defining a doping map representing a concentration of epitaxial dopant across the semiconductor substrate, using the doping map to create an implantation map dictating a degree to which at least one of the first portion and the second portion should be doped to create a second difference between the first average doping concentration level and the second average doping concentration level, where the second difference is less than the first difference, and performing a non-uniform ion implantation process on the semiconductor substrate in accordance with the implantation map.

A method for performing an ion implant dose split test to determine effects of different ion implantation doses in accordance with an embodiment of the present disclosure may include performing an ion implantation process on a semiconductor substrate, wherein a first portion of the semiconductor substrate is implanted with a first dose of a dopant and wherein a second portion of the semiconductor substrate is implanted with a second dose of the dopant, wherein the second dose is different than the first dose.

### BRIEF DESCRIPTION OF THE DRAWINGS

By way of example, various embodiments of the disclosed techniques will now be described with reference to the accompanying drawings, wherein:

FIG. 1 is a schematic view illustrating an example of an ion implantation system;

FIG. 2 is a flow diagram illustrating a method of performing non-uniform ion implantation in accordance with embodiments of the present disclosure;

FIG. 3A is a thermal map illustrating doping concentrations across a substrate;

FIG. 3B is a graph illustrating doping concentrations across the substrate shown in FIG. 3A;

FIG. 4A is a thermal map illustrating doping concentrations across a substrate after being subjected to a non-uniform implantation process according to the present disclosure;

FIG. 4B is a graph illustrating doping concentrations across the substrate shown in FIG. 4A;

FIG. 5A is a flow diagram illustrating a method of performing an ion implant dose split test in accordance with embodiments of the present disclosure;

FIG. 5B is a thermal map illustrating doping concentrations across a substrate resulting from the ion implant dose split test of FIG. 5A.

### DETAILED DESCRIPTION

The present embodiments will now be described more fully hereinafter with reference to the accompanying drawings, wherein some exemplary embodiments are shown. The subject matter of the preset disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Furthermore, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

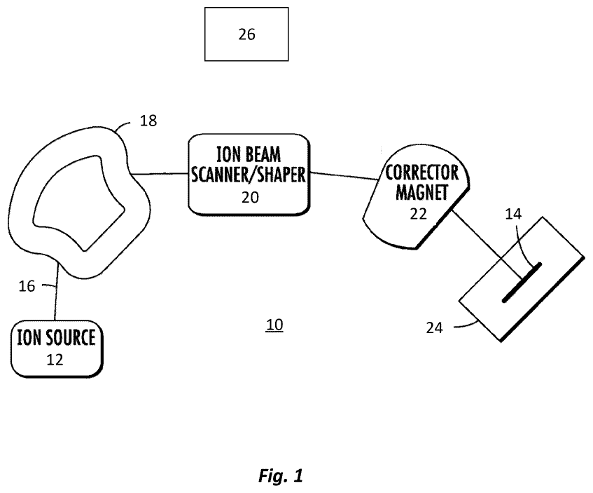

The present embodiments provide novel methods for improving doping uniformity in semiconductor substrates, and in particular using non-uniform ion implantation processes to correct non-uniform doping and defects resulting from epitaxial doping processes. The non-uniform ion implantation processes of the present disclosure may be performed using any suitable variety of ion implantation system adapted to implant a substrate using a spot beam. An example of such an ion implantation system 10 (hereinafter “the system 10”) is shown in FIG. 1. The system 10 may include an ion source 12, which typically is used to generate positive ions for implantation. The positive ions are provided as an ion beam that is deflected, accelerated, decelerated, shaped, and/or scanned between its emergence from the ion source 12 and a substrate 14 to be processed. An ion beam 16 is illustrated in FIG. 1 by a central ray trajectory (CRT). However, it will be appreciated by those of skill in the art, that an ion beam 16 has a finite width, height, and shape (e.g., a “spot”), which may vary along the beam path between the ion source 12 and substrate 14. FIG. 1 further depicts a mass analyzer 18 that deflects the ion beam, an electrostatic scanner 20, corrector magnet 22, and end station 24 that may manipulate the substrate 14 (e.g., move the substrate 14 in one or more directions orthogonal to the ion beam 16). In known systems, the electrostatic scanner 20 generates an electric field that is generally perpendicular to the direction of travel of ion beam 16 as it passes through the electrostatic scanner 20. The system 10 may further include a main controller 26 adapted to control and coordinate operation of the aforementioned components of the system 10 as further described below.

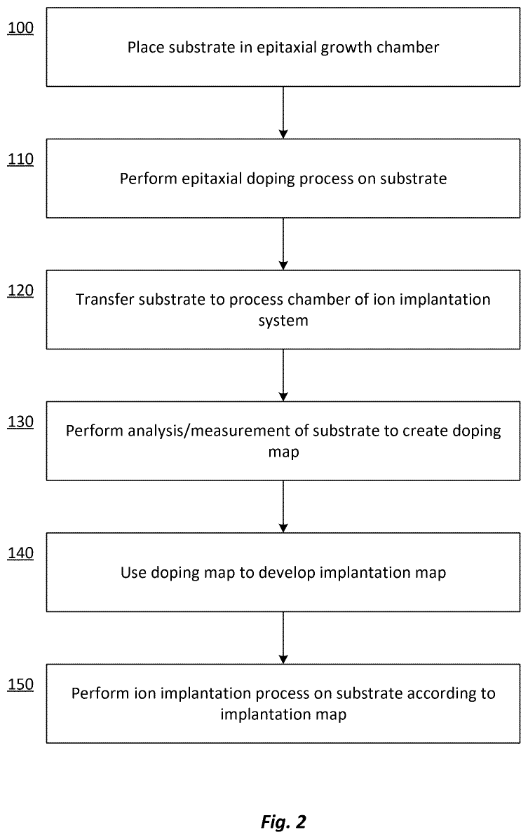

Referring to FIG. 2, a flow diagram illustrating an example of a method for using non-uniform ion implantation processes to correct non-uniform doping and defects resulting from epitaxial doping processes is shown. Referring to block 100 of the method depicted in FIG. 2, a semiconductor substrate (hereinafter “the substrate”) may be provided and may be disposed within an epitaxial growth chamber (hereinafter “the growth chamber”). The substrate may be formed of a wide bandgap material, such as silicon carbide, gallium nitride, gallium arsenide, diamond, etc. The present disclosure is not limited in this regard.

The growth chamber may be of any variety of epitaxial growth chamber known in the art and may be evacuated to create a low-pressure environment for mitigating contamination of the substrate and promoting uniform epitaxial growth. The growth chamber may be coupled to a precursor gas source and to a dopant gas source and may include temperature and pressure control systems as conventionally known.

At block 110 of the method depicted in FIG. 2, an epitaxial doping process may be performed on the substrate within the growth chamber. This process includes introducing precursor gases into the growth chamber from the precursor gas source, wherein the precursor gases contain semiconductor material to be deposited on the substrate. For silicon epitaxy, commonly used precursors include, and are not limited to, silane (SiH4) and dichlorosilane (SiCl2H2). These gases decompose at elevated temperatures, releasing silicon atoms that may form an epitaxial layer on the substrate. Controlled doping of the substrate is achieved by introducing dopant gases into the growth chamber from the dopant gas source along with the precursor gases. Common dopants used in silicon epitaxy include, and are not limited to, phosphine (PH3) for n-type doping and diborane (B2H6) for p-type doping. The doping concentration and distribution in the epitaxial layer defines the electrical properties of the resulting semiconductor device.

Temperature and pressure within the growth chamber may be precisely controlled (via the aforementioned temperature and pressure control systems of the growth chamber) throughout the epitaxial growth process. In a non-limiting example, temperatures ranging from 800° C. to 1200° C. may be used for silicon epitaxy to promote the decomposition of the precursor gases and to facilitate the diffusion of dopant atoms into the growing crystal lattice (other temperature ranges may be implemented for epitaxial growth of other materials). Pressure regulation maintains a stable growth environment and prevents undesired reaction within the growth chamber.

As the precursor gases decompose on the substrate surface, silicon atoms are deposited in a crystalline structure, forming an epitaxial layer. Simultaneously, dopant atoms are incorporated into the growing crystal lattice, creating a desired doping profile. The epitaxial layer's thickness and doping concentration are controlled by adjusting the deposition time and dopant flow rates. In various embodiments, advanced epitaxial growth systems may be implemented and may incorporate in-situ monitoring techniques such as spectroscopy or reflectometry to analyze the growth rate, thickness, and doping concentration of the epitaxial layer in real-time. This information facilitates precise control and optimization of the epitaxial layer's properties during growth.

Despite tightly controlling process parameters such as precursor and doping concentrations, temperature, pressure, etc., the above-described epitaxial doping process may nevertheless yield an epitaxial layer having significant non-uniformity across the surface of the substrate. This is especially true in substrates formed of wide bandgap materials such as silicon carbide, wherein defects and dislocations in the epitaxial layer are usually inevitable and are difficult to correct. Thus, after the above-described epitaxial doping process has been performed (including performing any cooling, annealing, and/or post growth processes known in the art), and in accordance with the novel techniques of the present disclosure, the substrate may, in block 120 of the method depicted in FIG. 2, be transferred to a process chamber of an ion implantation system.

The ion implantation system may be of any conventional variety having a plasma chamber wherein a dopant gas is ionized and is extracted and projected from the plasma chamber in the form of an ion beam (e.g., a spot beam) directed at the substrate in the process chamber. The substrate may be disposed on a motorized platen adapted to scan the substrate in directions perpendicular to the ion beam to expose selected portions of the substrate to the ion beam. By varying the speed with which the substrate is scanned, selected portions of the substrate may be doped more heavily relative to other portions. For example, a portion of the substrate that is scanned in front of the ion beam more slowly (i.e., a portion of the substrate upon which the ion beam is allowed to dwell for a longer period of time) will be more heavily doped than a portion of the substrate that is scanned in front of the ion beam more quickly (i.e., a portion of the substrate upon which the ion beam is allowed to dwell for a shorter period of time). An implantation process in accordance with the method of the present disclosure will be described in greater detail below.

The ion implantation system may include a main controller adapted to control and coordinate operation of the components of the ion implantation system. The main controller may include a processor, such as a known type of microprocessor, dedicated semiconductor processor chip, general purpose semiconductor processor chip, or similar device. The main controller may further include a memory or memory unit coupled to the processor, where the memory unit contains a control routine for controlling the operation of the components of the implanter in a predetermined manner. A desired implantation profile for the substrate may be achieved by providing the control routine with an “implantation map” that may dictate the speed with which various portions of the substrate are scanned in front of the ion beam (and thus the degree to which such portions are doped) as further described below.

After the substrate has been disposed within the process chamber of the ion implantation system (in block 120 of the method, described above), and prior to performing an ion implantation process on the substrate (as described below), an analysis/measurement of the substrate may be performed at block 130 of the method to assess a doping profile of the substrate resulting from the epitaxial doping process performed in block 110 of the method. For example, the ion implantation system may include metrology components including, and not limited to, an ellipsometer, a reflectometer, a pyrometer, an X-ray diffractometer, etc. adapted to facilitate measurement of various characteristics of the substrate, including the doping profile of the substrate. In various alterative embodiments, such measurement may be performed by metrology components outside of the ion implantation system, prior to the substrate being disposed within the process chamber of the ion implantation system (i.e., after block 110 but before block 120 of the method). The present disclosure is not limited in this regard.

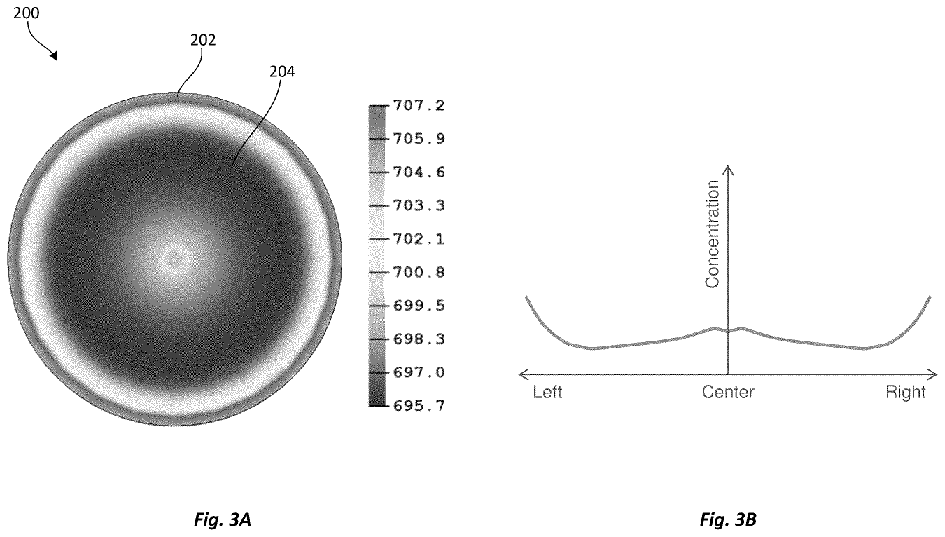

The measured doping profile may be stored (e.g., in the memory of the main controller) as a set of data defining a “doping map” representing the concentration of epitaxial dopant across the incoming substrate. As discussed above, the doping map may exhibit significant non-uniformity across the substrate as commonly associated with epitaxial doping of silicon carbide and other wide bandgap substrates. For example, a first portion of the doping profile may exhibit a first average doping concentration level (hereinafter “a first doping concentration”), and a second portion of the doping profile may exhibit a second average doping concentration level (hereinafter “a second doping concentration”), wherein the second doping concentration is less than the first doping concentration. A thermal map illustrating an example of a non-uniformly doped substrate 200 is shown in FIG. 3A, and a corresponding graph illustrating doping concentration across the substrate 200 is shown in 3B. The map and the graph reveal that the doping concentration is concentrically stratified. For example, the substrate 200 may include a radially outermost first portion 202 exhibiting a first doping concentration and a radially intermediate second portion 204 exhibiting a second doping concentration, wherein the first doping concentration is significantly greater than the second doping concentration.

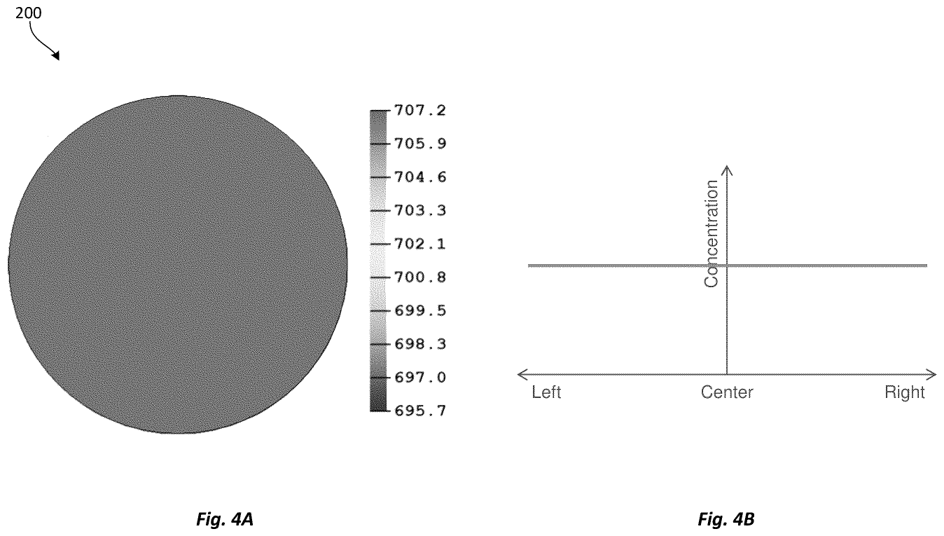

In order to remedy the non-uniform epitaxial doping of the substrate (i.e., in order to make the doping profile of the substrate more uniform), and in accordance with the novel techniques of the present disclosure, the processor of the main controller may, in block 140 of the method depicted in FIG. 2, use the doping map created in block 130 of the method to develop a compensatory implantation map to be used in an ion implantation process to be performed on the substrate. With reference to the example substrate 200 depicted in FIGS. 3A and 3B, if the doping map created in block 130 of the method shows that the first portion 202 of the substrate 200 exhibits a doping concentration that is relatively higher than a doping concentration of the second portion 204 of the substrate 200, an implantation map may be developed dictating that the second portion 204 will be doped (via ion implantation, as further described below) with the same species or type (i.e., n-type or p-type) of dopant used in the epitaxial doping process of block 110 of the method to make the doping concentration of the second portion 204 equal to (or nearly equal to) the doping concentration of the first portion 202. In another example, an implantation map may be developed dictating that both the first portion 202 and the second portion 204 will be doped (via ion implantation, as further described below) with the same species or type of dopant used in the epitaxial doping process of block 110 of the method to increase the doping concentrations of both the first portion 202 and the second portion 204 (by different amounts) to reach a common, target doping concentration across the substrate 200. In either case, prior to performing the implantation process according to the implantation map there may be a first difference between the doping concentration of the first portion 202 and the doping concentration of the second portion 204, and after performing the implantation process according to the implantation map there may be a second difference between the doping concentration of the first portion 202 and the doping concentration of the second portion 204, wherein the second difference is less than the first difference. For example, a thermal map illustrating the substrate 200 after performing the implantation process according to the implantation map is shown in FIG. 4A, and a corresponding graph illustrating doping concentration across the substrate 200 is shown in FIG. 4B. The map and the graph reveal that the doping concentration is across the substrate is generally uniform.

In another example, if the doping map created in block 130 of the method shows that the first portion 202 of the substrate 200 exhibits a doping concentration that is relatively higher than a doping concentration of the second portion 204 of the substrate 200, an implantation map may be developed dictating that the first portion 202 will be doped (via ion implantation, as further described below) with a different species or type of dopant used in the epitaxial doping process of block 110, wherein such different species or type of dopant is selected to counter dope the dopant used in block 110 of the method to effectively make the doping concentration of the first portion 202 equal to (or nearly equal to) the doping concentration of the second portion 204. That is, the ion implantation performed in block 140 of the method may have a counter effect to that of the epitaxial doping performed in block 110 of the method in the first portion 202. For example, in the case of silicon, if the dopant species used in the silicon epitaxial doping process of block 110 is phosphorus, the species selected for use in block 140 to counter dope the first portion 202 of the substrate 200 (i.e., the more heavily doped portion) may be boron. The present disclosure is not limited in this regard.

In yet another example, the doping map created in block 130 of the method may show that a various portions of the substrate 200 exhibit dislocations and/or defects resulting from the epitaxial growth process of block 110. In order to address such dislocations and/or defects, an implantation map may be developed dictating that the portions of the substrate 200 exhibiting the dislocations and/or defects will be irradiated (via ion implantation, as further described below) with hydrogen, which has been shown to suppress defects and pin down dislocation mobility in the crystalline lattice of a substrate.

At block 150 of the method of the present disclosure, the ion implantation system may be operated to perform an ion implantation process on the substrate 200 according to the implantation map developed in block 140. For example, portions of the substrate having lower concentrations of dopant may be implanted with the same species or type (i.e., n-type or p-type) of dopant used in the epitaxial doping process of block 110 of the method to make the doping concentration of such portions equal to (or nearly equal to) doping concentrations of portions of the substrate having higher doping concentrations, as dictated by the implantation map.

Alternatively, portions of the substrate having higher concentrations of dopant may be implanted with a different species or type of dopant used in the epitaxial doping process of block 110 to counter dope such portions and effectively make the doping concentrations of such portions equal to (or nearly equal to) the doping concentrations of portions of the substrate having lower doping concentrations, as dictated by the implantation map. In another alternative, portions of the substrate having dislocations and/or defects may be implanted with hydrogen in order to suppress defects and pin down dislocation mobility, as dictated by the implantation map. More generally, in all of the above-described examples, the ion implantation process performed in block 150 of the method may utilize a targeted, non-uniform implantation to remedy non-uniformities and/or defects in the substrate.

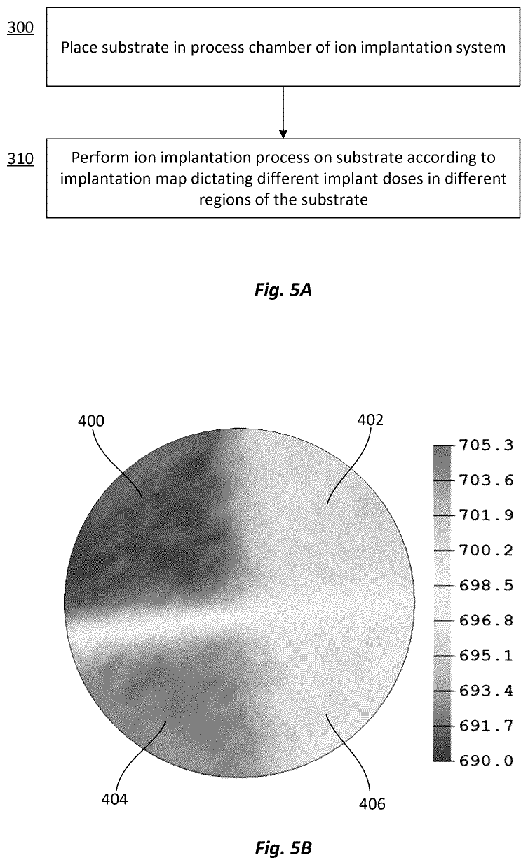

In addition to addressing non-uniformities and/or defects resulting from epitaxial growth processes, the non-uniform implantation process of the present disclosure may be beneficially applied in various other applications. For example, referring to FIG. 5A, a flow diagram illustrating a method wherein non-uniform implantation is used to perform an “ion implant dose split test” is shown. In block 300 of the method, a substrate may be placed in a process chamber of an ion implantation system. At block 310 of the method, the ion implantation system may be operated to perform an ion implantation process on the substrate according to an implantation map dictating that a first region of the substrate be implanted with a first dose of a dopant and that a second region of the substrate be implanted with a second dose of the dopant, wherein the second dose is different than the first dose. The total number of regions and corresponding different doses may be greater than two and may be any number that may be practically implemented on a single substrate. For example, referring to FIG. 5B, a thermal map illustrating a substrate having four different regions 400, 402, 404, 404 doped with four different doses is shown. Thus, unlike conventional dose tests, wherein implants of different doses are performed on separate substrates to determine the effects of such doses, the method of the present disclosure allows such a test to be performed using a single substrate. That is, the effects of numerous different implant doses can be viewed on one substrate. This dramatically reduces the amount of amount of material (i.e., the number of substrates) needed to perform dose tests, and also eliminates the need to consider wafer-to-wafer non-uniformity, which must be taken into account when performing conventional, muti-wafer dose testing.

The of skill in the art will appreciate the numerous advantages provided by the methods of the present disclosure. For example, the methods of present disclosure facilitate the improvement of doping uniformity in substrates that exhibit non-uniformity resulting from epitaxial growth processes. Furthermore, the methods of present disclosure facilitate the targeted correction of defects and dislocations in substrates. Still further, the methods of present disclosure facilitate dose testing using a single substrate.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A method for improving doping uniformity in a semiconductor substrate, the method comprising:
placing the semiconductor substrate in an epitaxial growth chamber;
performing an epitaxial doping process on the semiconductor substrate, whereafter a first portion of the semiconductor substrate exhibits a first average doping concentration level and a second portion of the semiconductor substrate exhibits a second average doping concentration level, where there is first difference between the first average doping concentration level and the second average doping concentration level;
transferring the substrate to a process chamber of an ion implantation system; and
performing a non-uniform ion implantation process on the semiconductor substrate to create a second difference between the first average doping concentration level and the second average doping concentration level, where the second difference is less than the first difference.

2. The method of claim 1, wherein performing the epitaxial doping process comprises doping the semiconductor substrate with a first dopant, and wherein performing the non-uniform ion implantation process comprises implanting the second portion of the semiconductor substrate with the first dopant to create the second difference.

3. The method of claim 1, wherein performing the epitaxial doping process comprises doping the semiconductor substrate with a first dopant, and wherein performing the non-uniform ion implantation process comprises implanting the first portion of the semiconductor substrate with a second dopant selected to counter dope the first dopant to create the second difference.

4. The method of claim 1, further comprising:
performing an analysis of the semiconductor substrate after performing the epitaxial doping process to determine a doping profile of the semiconductor substrate; and
storing the doping profile as a set of data defining a doping map representing a concentration of epitaxial dopant across the semiconductor substrate.

5. The method of claim 4, further comprising using the doping map to create an implantation map dictating a degree to which the first portion and the second portion should be doped during the non-uniform ion implantation process.

6. The method of claim 4, wherein the analysis is performed on the semiconductor substrate prior to the semiconductor substrate being transferred to the process chamber of the ion implantation system.

7. The method of claim 4, wherein the analysis is performed on the semiconductor substrate in the process chamber of the ion implantation system.

8. The method of claim 1, wherein performing the non-uniform ion implantation process on the semiconductor substrate comprises implanting portions of the semiconductor substrate exhibiting dislocation or defects with hydrogen to suppress the defects and pin down dislocation mobility.

9. The method of claim 1, wherein the semiconductor substrate is formed of a wide bandgap material.

10. The method of claim 9, wherein the semiconductor substrate is formed of one of silicon carbide, gallium nitride, gallium arsenide, and diamond.

11. A method for improving doping uniformity in a semiconductor substrate, the method comprising:
placing the semiconductor substrate in an epitaxial growth chamber;
performing an epitaxial doping process on the semiconductor substrate, whereafter a first portion of the semiconductor substrate exhibits a first average doping concentration level and a second portion of the semiconductor substrate exhibits a second average doping concentration level, where there is first difference between the first average doping concentration level and the second average doping concentration level;
transferring the substrate to a process chamber of an ion implantation system;
performing an analysis of the semiconductor substrate to determine a doping profile of the semiconductor substrate;
storing the doping profile as a set of data defining a doping map representing a concentration of epitaxial dopant across the semiconductor substrate;
using the doping map to create an implantation map dictating a degree to which at least one of the first portion and the second portion should be doped to create a second difference between the first average doping concentration level and the second average doping concentration level, where the second difference is less than the first difference; and
performing a non-uniform ion implantation process on the semiconductor substrate in accordance with the implantation map.

12. The method of claim 11, wherein performing the epitaxial doping process comprises doping the semiconductor substrate with a first dopant, and wherein performing the non-uniform ion implantation process comprises implanting the second portion of the semiconductor substrate with an additional quantity of the first dopant to create the second difference.

13. The method of claim 11, wherein performing the epitaxial doping process comprises doping the semiconductor substrate with a first dopant, and wherein performing the non-uniform ion implantation process comprises implanting the first portion of the semiconductor substrate with a second dopant selected to counter dope the first dopant to create the second difference.

14. The method of claim 11, wherein the analysis is performed on the semiconductor substrate prior to the semiconductor substrate being transferred to the process chamber of the ion implantation system.

15. The method of claim 11, wherein the analysis is performed on the semiconductor substrate in the process chamber of the ion implantation system.

16. The method of claim 11, wherein performing the non-uniform ion implantation process on the semiconductor substrate comprises implanting portions of the semiconductor substrate exhibiting dislocation or defects with hydrogen to suppress the defects and pin down dislocation mobility.

17. The method of claim 11, wherein the semiconductor substrate is formed of a wide bandgap material.

18. The method of claim 17, wherein the semiconductor substrate is formed of one of silicon carbide, gallium nitride, gallium arsenide, and diamond.

19. A method for performing an ion implant dose split test to determine effects of different ion implantation doses, the method comprising:
performing an ion implantation process on a semiconductor substrate, wherein a first portion of the semiconductor substrate is implanted with a first dose of a dopant and wherein a second portion of the semiconductor substrate is implanted with a second dose of the dopant, wherein the second dose is different than the first dose.
